(19) United States
(12) Patent Application Publication
(10) Pub. No.: US 2013/0337615 A1
(43) Pub. Date: Dec. 19, 2013

(54) POLYMER HOT-WIRE CHEMICAL VAPOR DEPOSITION IN CHIP SCALE PACKAGING

(71) Applicant: APPLIED MATERIALS, INC., Santa Clara, CA (US)

(72) Inventors: Jingjing XU, San Jose, CA (US); Joe Griffith CRUZ, San Jose, CA (US)

(73) Assignee: APPLIED MATERIALS, INC., Santa Clara, CA (US)

(21) Appl. No.: 13/902,516

(22) Filed: May 24, 2013

Related U.S. Application Data
(60) Provisional application No. 61/652,133, filed on May 25, 2012.

(51) Int. Cl. H01L 21/02

(52) U.S. Cl. CPC H01L 21/02112
USPC 438/125; 438/667; 438/759

(57) ABSTRACT

Embodiments of the present invention provide a vapor phase organic polymer film deposited using a CVD process at low temperature during a process sequence for wafer-level chip scale packaging (WL-CSP), including system-in package (SiP), Package-on-Package (PoP) and Package-in-Package (PiP).

### CROSS-REFERENCE TO RELATED APPLICATIONS

This application claims benefit of U.S. Provisional Patent Application Ser. No. 61/652,133, filed May 25, 2012, which is herein incorporated by reference.

### BACKGROUND OF THE INVENTION

1. Field of the Invention

Embodiments of the present invention generally relate to an apparatus and a method of forming an organic polymer material film that may be used in wafer level packaging, and chip scale packaging.

2. Description of the Related Art

Three-dimensional integrated circuits (3D-ICs) are a type of chip packaging done at the wafer level to streamline the manufacturing process. Using 3D-IC fabrication, multiple chips are vertically stacked in a single package to deliver higher performance and functionality in a smaller area. The chips are electrically connected to one another within the stack using holes through the chips called through-silicon vias (TSVs). Flip-chip technology is a manufacturing process that is a versatile and low-cost method of electrically connecting the TSVs and combining multiples of chips into a single package stack. 3D-ICs using flip-chip processing methodology is widely used in applications such as digital signal processors, driver chips, smart cards and MEMS devices.

Historically, wire bonding has been the approach used to connect a chip device to a substrate during the chip packaging. These connections are limited to the outer perimeter of the device, thereby limiting input/output (I/O) density. Furthermore, the presence of wire bonds extending beyond the chip device increases the real estate necessary for the final device package. For high-speed devices, the use of wire bonds will also limit performance due to signal delays.

To enable a flip-chip manufacturing method, a growing number of advanced chip devices are fabricated using under bump metallization (UBM) to connect multiple chips in a vertically stacked chip package. UBM includes conductive pads or bumps deposited on and connected to the device circuitry on the top metal level of the device after conventional wafer processing and fabrication is complete. A solder material is then used to directly connect the device to the packaging substrate.

In UBM, the connection points between the chip device and the packaging substrate are distributed over the entire top surface of the chip resulting in an increased I/O density by using a higher percentage of the chip surface area for connection to the packaging substrate. In addition, the direct connection between the chip and the packaging substrate results in a reduced form factor and high speed performance relative to wire bonding.

Redistribution layers (RDLs) are used in UBM as conductive metal lines formed to reroute wire bonding connections from the edge to the center of a chip device. After the redistribution layer is formed, the chip packaging process flow can continue using UBM metallization instead of conventional wire bonding. RDLs can also be used to use existing package substrates while accommodating the smaller chip die produced by semiconductor manufacturers transitioning to advanced technology nodes. The deposition of RDLs before bonding is required as part of 3D-IC process integration flow.

There have been increasing challenges in electronic packaging due to the reduction in component sizes. Flip chip manufacturing techniques provide a method of using solder to bond and interconnect IC chips and MEMS devices to external circuitries. Polyimide materials are widely used in the flip chip packaging process as encapsulents, coatings, adhesives and wafer underfill between the stacked chips. Spin coating is one current method of applying the polyimide materials, but includes limitations such as the requirement of high temperature curing. High temperature curing provides for high material shrinkage and high moisture absorption. High material shrinkage causes bowing of the substrates and high moisture absorption causes outgassing, both of which lead to delamination of the chip package.

There is a need for an integrated process sequence using conformal and bottom-up fill functional polymer films in 3D wafer-level packaging scheme for wafer level, chip scale packaging (WL-CSP).

### SUMMARY OF THE INVENTION

Embodiments of the present invention provide a vapor phase organic polymer film deposited at low temperature during a process sequence for WL-CSP, including system-in package (SiP), Package-on-Package (PoP) and Package-in-Package (PiP).

Embodiments of the present invention may provide a method of processing a substrate comprising depositing a polymer layer over a surface of a substrate having solder disposed thereon using a low temperature CVD technique, and bonding the substrate to an external circuitry by heating the solder.

Embodiments of the present invention may also provide a method of processing a substrate comprising forming one or more holes into or through a substrate, forming a polymer liner conformally over a surface of the substrate and on sidewalls of the one or more holes using a low temperature CVD technique, and filling the one or more holes with a conductive material.

Embodiments of the present invention may additionally provide a method of processing a substrate comprising polishing the surface of a substrate, the substrate having holes therein that are filled with conductive material, and stopping the polishing upon reaching the conductive material, and forming a polymer film over the substrate using a low temperature CVD technique, and polishing the polymer film and stopping the polishing upon reaching the conductive material.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic side view of a PHCVD process chamber suitable for use in accordance with embodiments of the present invention.

FIG. 2 is a flow diagram of a method 300 for depositing a vapor phase organic polymer film on a substrate at low temperature using the PHCVD processing chamber, as described above with reference to FIG. 1.

FIGS. 3A-3E illustrates a process for forming TSVs and using a vapor phase polymer film as a TSV liner between a via fill material and the surrounding substrate.

FIGS. 4A-4H show a process for forming TSVs and using a vapor phase polymer film as a gap fill material and via support material during wafer polishing

FIG. 5 illustrates a prior art method of depositing underfill material between a chip and substrate during a chip packaging process.

FIG. 6 illustrates the use of a vapor phase organic polymer film as underfill material in a flip chip packaging process.

FIG. 7 illustrates a cross-sectional view of a portion of a stack structure of a semiconductor package.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION OF THE INVENTION

Embodiments of the present invention generally provide an organic polymer film deposited using low temperature CVD processes to form organic polymer films useful for WL-CSP, including SiP, PoP and PiP. The low temperature deposition processes use one or more monomer and initiator gases to form polymer films at temperatures lower than traditional high temperature CVD techniques. The polymer films may be deposited using the low temperature CVD techniques as described herein, and may include flowing the gases past a heated showerhead, heated filament wires or both. The deposition processes will be described below with reference to a polymer hot-wire chemical vapor deposition (PHCVD) process using a hot-wire CVD chamber. However, a CVD chamber using a heated showerhead may also be used and is referenced in suitable sections below. Polymer thin films deposited using CVD process such as a PHCVD technique at low temperature (e.g., at room temperature or a temperature of 60° C. and below) provides an underfill material that eliminates the need for the use of harmful solvents used in typical underfill materials currently used for wafer level packaging. By eliminating the use of solvents, there is no outgassing that can cause high contact resistance Rc in the formed contacts. In addition, the annealing temperature for the organic polymer film is low (e.g., between 50° C. and 70° C.). The use of the organic polymer film prevents/minimizes wafer bowing caused by curing at high temperatures. In addition, the polymer film provides for a low-k film that is photo-sensitive and may be patterned directly using UV lithography.

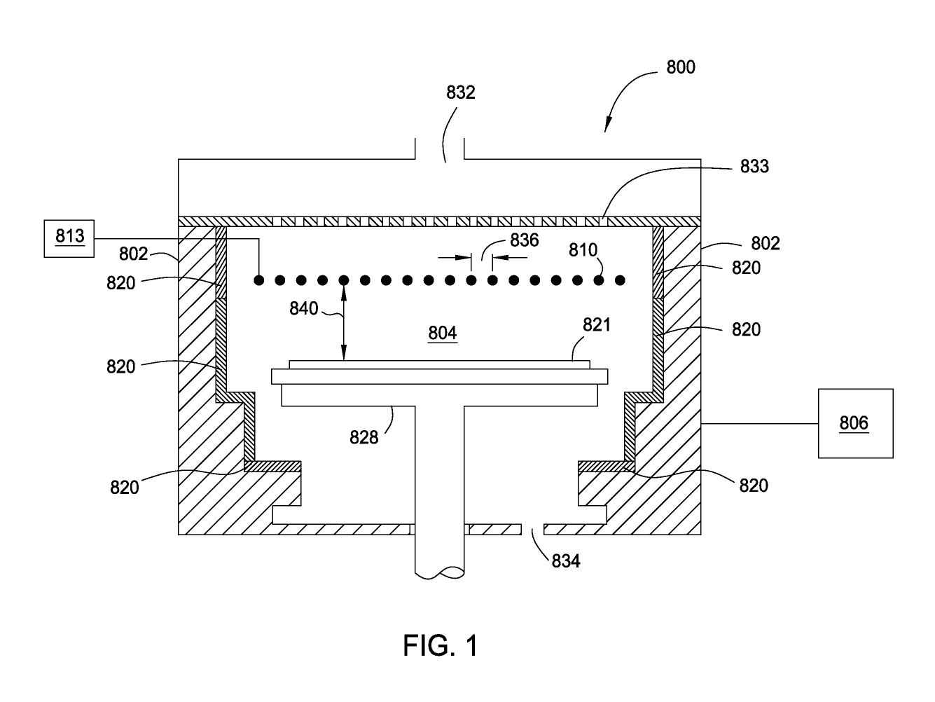

FIG. 1 depicts a schematic side view of a PHCVD process chamber 800 suitable to form organic polymer films in accordance with embodiments, herein. The process chamber 800 generally comprises a chamber body 802 having an internal processing region 804. A plurality of filaments, or wires 810, are disposed within the chamber body 802 (e.g., within the internal processing region 804). The plurality of wires 810 may also be a single wire routed back and forth across the internal processing region 804. The plurality of wires 810 collectively form a PHCVD temperature source. The wires 810 may comprise any suitable conductive material, for example, such as a steel alloy. The wires 810 may be of any thickness suitable to provide a desired temperature to facilitate a process in the process chamber 800. For example, in some embodiments, each wire 810 may comprise a diameter of about 0.2 to about 1 mm. Each wire 810 is clamped in place by support structures to keep the wire taught when heated to high temperature, and to provide electrical contact to the wire. In some embodiments, a distance between each wire 810 (i.e., the wire to wire distance 836) may be varied to provide a desired temperature profile within the process chamber 800. For example, in some embodiments, the wire to wire distance 836 may be about 10 to about 60 mm.

Power supply 813 is coupled to the wire 810 to provide current to heat the wire 810. Substrate 821 may be positioned under the PHCVD source (e.g., the wires 810), for example, on a substrate support 828. In some embodiments, a distance between each wire 810 and substrate 821 (i.e., the wire to substrate distance 840) may be varied to facilitate a particular process being performed in the process chamber 800. For example, in some embodiments, the wire to substrate distance 840 may be about 10 to about 60 mm.

The chamber body 802 further includes one or more gas inlets (one gas inlet 832 shown) to provide one or more process gases and one or more outlets 834 to a vacuum pump to maintain a suitable operating pressure within the process chamber 800 and to remove excess process gases and/or process byproducts. The gas inlet 832 may feed into a showerhead 833, or other suitable gas distribution element, to distribute the gas uniformly, or as desired, over the wires 810. The showerhead 833 may be a heated showerhead to further enhance the temperature control within the chamber. The showerhead 833 may be connected to a power source to supply heat to the showerhead.

In some embodiments, one or more chamber liners 820 may be provided to minimize unwanted deposition on interior surfaces of the chamber body 802. The use of liners may preclude or reduce the use of undesirable cleaning gases, such as the greenhouse gas NF₃. Chamber liners 820 generally protect the interior surfaces of chamber body 802 from undesirably collecting deposited materials due to the process gases flowing in the chamber. Chamber liners 820 may be removable, replaceable, and/or cleanable. Chamber liners 820 may be configured to cover every area of the chamber body that could become coated, including but not limited to the all walls of the coating compartment. Typically, chamber liners 820 may be fabricated from aluminum (Al) and may have a roughened surface to enhance adhesion of deposited materials (to prevent flaking off of deposited material). Chamber liners 820 may be positioned in the desired areas of the process chamber, such as around connection points for wires 810, in any suitable manner. In some embodiments, the wires 810 and liners 820 may be removed for maintenance and cleaning by opening an upper portion of the deposition chamber.

Controller 806 may be coupled to various components of the process chamber 800 to control the operation thereof. Although schematically shown coupled to process chamber 800, controller 806 may be operably connected to any component that may be controlled by controller 806, such as power supply 813 a gas supply (not shown) coupled to inlet 832, a vacuum pump and/or throttle valve (not shown) coupled to outlet 834, substrate support 828, and the like, in order to control the PHCVD deposition process in accordance with the methods described below.

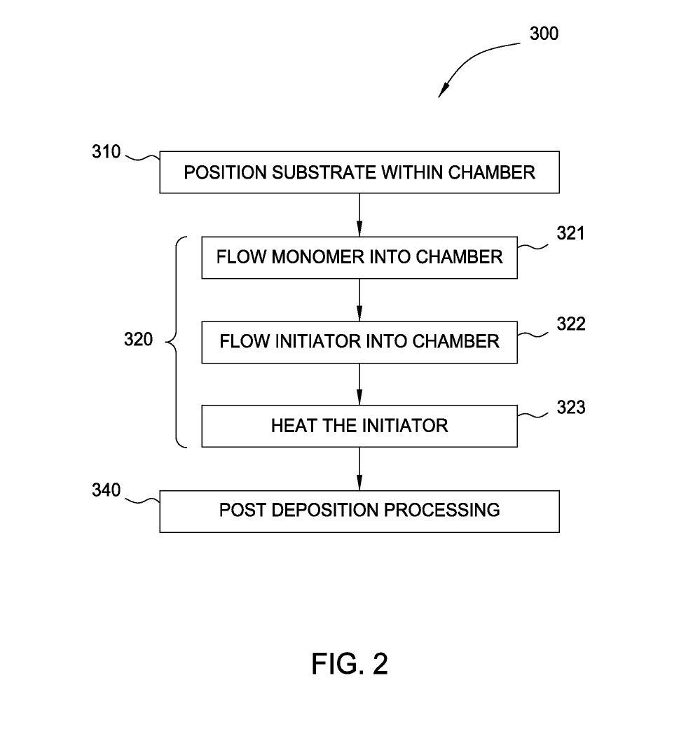

FIG. 2 is a flow diagram of a method 300 for depositing a vapor phase organic polymer film on a substrate at low temperature using the PHCVD processing chamber 800, as described above. The vapor phase organic film, once deposited, is then integrated post deposition as enhanced wafer level packaging features. The film may be deposited around/over solder balls on a surface of the substrate and/or may be deposited in holes formed through the substrate, such as TSVs as part of a wafer packaging process. Vapor phase organic polymer films deposited by a PHCVD method eliminate the use of plasma and therefore, the polymer film maintains the functionalities (bonding sequence) in the polymer film that would otherwise be destroyed by the high temperature plasma.

Referencing FIG. 2 in conjunction with FIG. 1, method 300 begins at step 310 with the deposition of the polymer film. Substrate 821 is positioned on substrate support assembly 828 within process chamber 800. To facilitate the deposition of the organic polymer material, substrate 821 may be positioned under a hot wire source (wires) 810 such that substrate 821 is exposed to the process gas and decomposed species thereof, thereby allowing the material to deposit on the substrate 821 and form the polymer film. In certain embodiments, the substrate 821 may be positioned under a heated showerhead or under both a heated showerhead and wires 810.

Substrate 821 may be provided to chamber 800 either before or after the heating of wires 810, but typically prior to providing the process gas to the chamber. Substrate 821 may be any suitable substrate for a desired application, such as a doped or un-doped silicon substrate, a III-V compound substrate, a silicon germanium (SiGe) substrate, a silicon nitride (SiN) substrate, an epi-substrate, a silicon-on-insulator (SOI) substrate, a substrate comprising one or more metals such as copper (Cu), a display substrate such as a liquid crystal display (LCD), a plasma display, an electro luminescence (EL) lamp display, a light emitting diode (LED) substrate, a solar cell array, solar panel, or the like. In some embodiments, substrate 821 may be a semiconductor wafer. In some embodiments, substrate 821 may be a large scale LCD or glass substrate, for example, such as an about 1000 mm×1250 mm substrate or an about 2200 mm×2500 mm substrate. In certain embodiments such as further described herein, substrate 821 is a silicon substrate of a semiconductor chip with circuitry provided therein and designed to be processed and stacked within a wafer packaging scheme.

Step 320 includes the deposition process steps for forming a vapor phase deposited polymer film and includes providing process gases to the process chamber 800 and heating the gases as described in detail below with regards to process steps 321-323. The process gases include at last two precursors, such as an initiator and monomer. The monomer is introduced into the chamber 800 and adsorbed on the surface of the substrate. The initiator is activated by the temperature of wires 810 and used to initiate the polymerization of monomers that are adsorbed on the surface of substrate 821. The monomers react with the activated initiator species and begin polymerization. The mechanical and electrical properties, such as adhesion, strength and CTE, of the polymer film can be tuned by using different monomers. The conformality of the polymer film can be further controlled via process conditions, such as filament temperature, pedestal temperature, pressure and flow rates, etc. The deposited polymer film may be used in a number of applications including as a TSV liner, as gap fill material supporting the TSV structure during a wafer polishing step in the flip-chip process and as underfill material in the flip-chip process, each of which are described in detail below.

Since the deposition process is driven by surface adsorption, the desired film characteristics and step coverage can be tuned by process parameters and chamber conditions such as substrate temperature, chamber pressures, gas flow rates, filament temperature, showerhead temperature, process times and choice of precursors.

Generally, the temperatures for the PHCVD growth of the organic polymer film may range from about 100 degrees Celsius (° C.) to about 450° C., although temperatures lower than 600° C. may be used. The chamber pressures may range from about 100 mTorr to about 1 atmosphere, but more preferably from about 0.1 Torr to about 100 Torr. In certain embodiments, the chamber pressure may range from about 400 mTorr to about 700 mTorr. In certain embodiments, the chamber pressure may be less than 1,000 mTorr. In certain embodiments, the chamber pressure may be less than 400 mTorr, although lower or higher pressures may also be used.

The growth time or “residence time” depends in part on the desired thickness of the organic polymer film, with longer growth times producing thicker films. The growth time may range from about ten seconds to many hours, but more typically from about ten minutes to several hours.

The temperature of the filament wires 810 for the PHCVD process is generally dependent upon the initiator source gas. For example, the temperature of the filament wires 810 for the PHCVD growth of organic polymer film may range from about 100° C. to about 600° C. for example from between about 100° C. and about 450° C. In certain embodiments, the substrate support temperature is maintained between 10° C. and 75° C. In one embodiment, the temperature of the substrate 121 may be about room temperature (e.g. about 20 to 25° C.).

Step 321 is the process step of flowing a monomer gas into the processing region 804 of the chamber, preferably through showerhead 833. Flowing the monomer through showerhead 833 facilitates an even distribution of the adsorption of the monomer on the surface of the substrate 821, resulting in a uniform deposited polymer film. The monomer gas used for the deposition of vapor phase organic polymer, as described herein, may comprise ethyleneglycol diacrylate, t-butylacrylate, N,N-dimethylacrylamide, vinylimidazole, 1-3-diethynylbenzene, 4-vinyl pyridine, poly vinyl pyridine, poly 4-vinyl pyridine, polyphenylacetylene, N,N-dimethylaminoethylmethacrylate, divinylbenzene, poly divinylbenzene, glycidyl methacrylate, poly thiophene, ethyleneglycol dimethacrylate, tetrafluoroethylene, dimethylaminomethylstyrene, perfluoroalkyl ethyl methacrylate, trivinyltrimethoxy-cyclotrisiloxane, furfuryl methacrylate, cyclohexyl methacrylate-co-ethylene glycol dimethacrylate, pentafluorophenyl methacrylate-co-ethylene glycol diacrylate, 2-hydroxyethyl methacrylate, methacrylic acid, 3,4-ethylenedioxythiophene, and combinations thereof. In certain embodiments the monomer gas may be an aromatic monomer. In certain embodiments, the monomer is flown into the process chamber at a temperature of between about 55° C. and about 75° C.

In certain embodiments, the monomer may further comprise a gaseous cross-linker source gas. Gases cross-linker source gases facilitate the cross-linking of the polymer atoms, particularly when using combinations of monomers. Gaseous cross-linker source gases include, but are not limited to, 2-ethyl- 2(hydroxymethyl)propane-trimethyacrylate (TRIM), acrylic acid, methacrylic acid, trifluoro-methacrylic acid, 2-vinylpyridine, 4-vinylpyridine, 3(5)-vinylpyridine, p-methylbenzoic acid, itaconic acid, 1-vinylimidazole, ethylene glycol dimethacrylate, and combinations thereof.

Step 322 is the process step of flowing an initiator gas into chamber 800. The initiator gas is provided to the processing region 804 of chamber 800 by flowing through the showerhead 833 and past the filament wires 810 as described in reference to step 323, below, and FIG. 1.

The initiator source gas may comprise any initiator-containing gas or gases, and the initiator source gas may be obtained from liquid or solid precursors. More specifically, the initiator source gas may include, but not limited to, hydrogen peroxide, alkyl peroxides, aryl peroxides, hydroperoxides, halogens, azo compounds, and combinations thereof. In certain embodiments, the initiator source gas may be selected from the group comprising perfluorooctane sulfonyl fluoride (PFOS), perfluorobutane-1-sulfonyl fluoride (PFBS), triethylamine (TEA), tert-butyl peroxide (TBPO), 2,2′-azobis (2-methylpropane), tert-amyl peroxide (TAPO), di-tert-amyl peroxide, antimony pentachloride and benzophenone, and combinations thereof.

In some embodiments, the process gases may comprise additional gases, such as, for example, a carrier gas, dilutant gas, or the like. In such embodiments, the additional gases may comprise inert gases, such as for example, helium (He), neon (Ne), argon (Ar), or the like. In some embodiments, the inert gas may be provided at a flow rate of about 10 to about 100 sccm. In some embodiments, the inert gas may be argon (Ar).

Step 323 is the process step of heating the initiator source gas by flowing an initiator into the processing region 804 past one or more filament wires 810 heated to a temperature between about 100° C. and about 450° C. Alternatively, or in combination, the initiator may be heated from a heated showerhead. The heat from heated wires 810 and or heated showerhead dissociates the initiator gases into reactive species, e.g. radicals. The activated initiator species react/cross link with the monomer species on the surface of the substrate to begin the polymerization reaction to deposit a polymer film on the substrate. The initiator and monomer may be provided in any ratio necessary to form the desired polymer film. For example, in some embodiments, the initiator and monomer may be provided in a ratio of initiator to monomer of about 1:10 to about 1:1. In some embodiments, the initiator and monomer may be provided to the processing chamber together, or in some embodiments, provided separately to the processing chamber and allowed to mix within the chamber during processing.

The resulting organic polymer film deposited by vapor phase deposition may be a polymer selected from the group consisting of poly(glycidyl methacrylate-co-divinylbenzene), poly(glycidyl methacrylate-co-methacrylamide), poly(ethyleneglycol diacrylate), poly(t-butylacrylate), poly N,N-dimethylacrylamide, poly(vinylimidazole), poly(1-3-diethynylbenzene), poly(phenylacetylene), poly(N,N-dimethylaminoethylmethacrylate) (p(DMAM), poly (divinylbenzene), poly(glycidyl methacrylate) (p(GMA)), poly (ethyleneglycol dimethacrylate), poly (tetrafluoroethylene), poly(tetrafluoroethylene) (PTFE), poly(dimethylaminomethylstyrene) (p(DMAMS), poly(thiophene), poly(vinylpyridine), poly(perfluoroalkyl ethyl methacrylate), poly(trivinyltrimethoxy-cyclotrisiloxane), poly(furfuryl methacrylate), poly(cyclohexyl methacrylate-co-ethylene glycol dimethacrylate), poly(pentafluorophenyl methacrylate-co-ethylene glycol diacrylate), poly(2-hydroxyethyl methacrylate-co-ethylene glycol diacrylate), poly(methacrylic acid-co-ethylene glycol dimethacrylate), poly(3,4-ethylenedioxythiophene), and combinations thereof.

The resulting vapor phase polymer film deposited by the above discussed PHCVD processes provides enhanced film characteristics over films deposited by conventional CVD process, including a stoichiometric film that retains its full polymer functionality and which may be patterned directly using typical photoresist processes. The deposited polymer film has increased mechanical strength and adhesion properties, with low moisture content and does not require a high temperature anneal process.

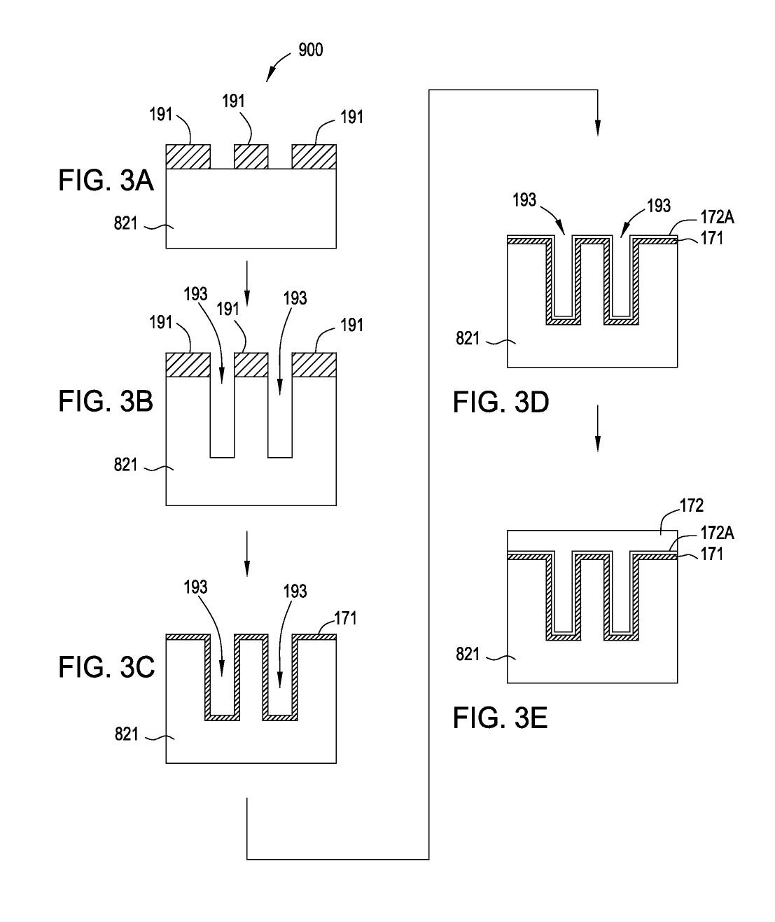

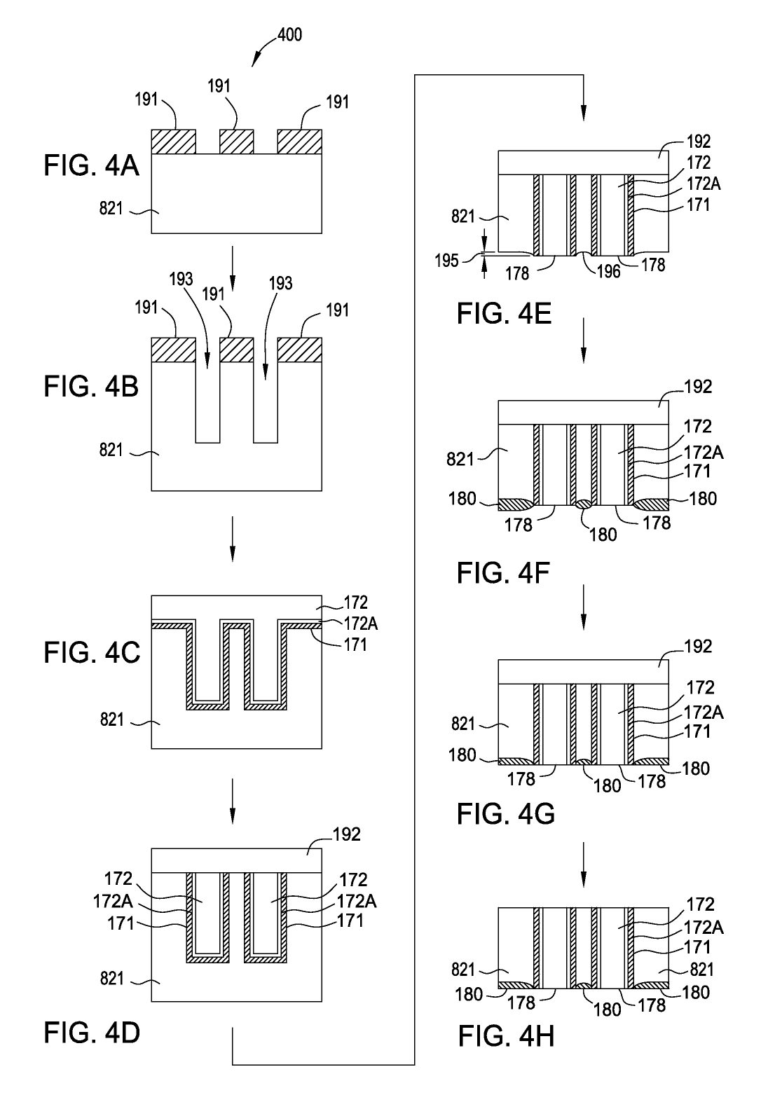

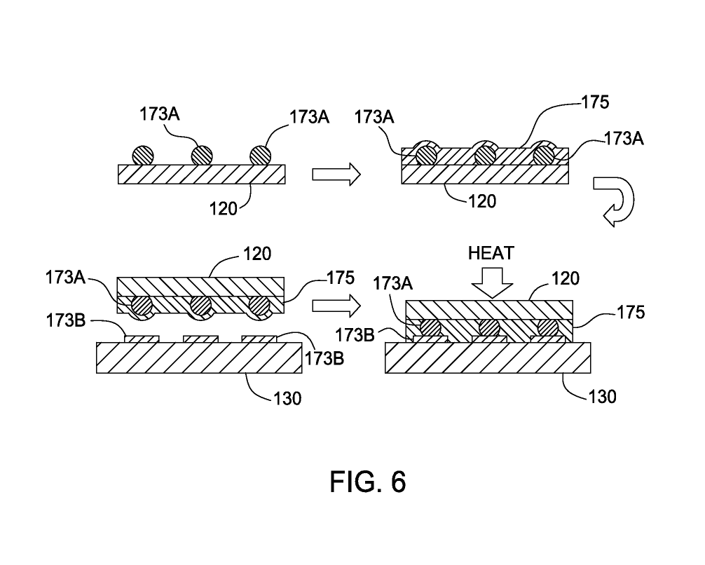

After depositing the organic polymer film, the deposition step 320 generally ends and substrate 821 may proceed for further processing, such as step 340. In some embodiments, step 340 may include additional processes such as layer deposition, etching, annealing, or the like, that may be performed on substrate 821. For example, as discussed below with reference to FIGS. 3A-3E and FIGS. 4A-4H, additional films may be deposited such as barrier films and copper interconnect films, and/or the substrate may be integrated directly into a flip-chip packaging process step where the organic polymer film is used as gap fill and underfill material, as shown in FIG. 6, and as used in WL-CSP, including SiP, PoP and PiP.

Vapor Phase Organic Polymer Film as a TSV Liner

FIGS. 3A-3E illustrate a process 900 for forming TSVs and using a vapor phase polymer film as a TSV liner between a via fill material and the surrounding substrate. TSVs are used to connect chips in wafer-level chip scale packaging. However, during the manufacturing process, and before filling the TSV with a conductive via fill material, such as copper, a dielectric liner 171 must be deposited as a low-k dielectric insulator between the conductive via fill material and the silicon substrate. Plasma deposited silicon dioxide is typically used as a liner material, but the deposition process takes place at a relatively high temperature, deposits films with higher dielectric constant (k=3.9), high moisture content, and relatively poor conformality. However, the deposition of polymer films as described above with reference to FIGS. 1 and 2 provides for a TSV liner application that reduces oxidation of the conductive metal interconnect due to its lower moisture content, reduces Rc delay and reduces current leakage. In addition, the polymer film deposition process enables low temperature deposition and provides for a film with high step coverage on high aspect ratio vias, and with low moisture content/absorption. Furthermore, because the deposition process is a vapor phase process, monomers may be selected to deposit a film with a low and ultra low dielectric constant and the deposited organic polymer film does not require curing.

FIG. 3A shows a cross sectional side view of silicon substrate 821 with patterned resist 191 on the surface of the substrate. FIG. 3B shows deep holes 193 formed within substrate 121. Holes 193 may be formed using traditional etch processes. Alternatively, holes 193 may be formed by drilling. The resist pattern is removed using traditional techniques.

FIG. 3C shows a cross sectional side view of substrate 821 with liner 171 deposited conformally over the surface of substrate 821 and including the side walls of holes 193. The liner 171 is deposited using a vapor phase polymer deposition process and PHCVD chamber as disclosed above.

Exemplary monomer source gases that may be used to meet liner requirements may include poly divinyl benzene, poly vinyl pyridine and poly thiophene derivitives. Exemplary source gas initiators that may be used to meet liner requirements may include antimony pentachloride, tert-butyl peroxide (TBPO) and tert-amyl peroxide (TAPO). Other monomer and initiator source gases as described herein, may also be used. The resulting film serves as a TSV liner application that reduces oxidation of the subsequently deposited conductive metal interconnect due to its lower moisture content, reduces Rc delay and reduces current leakage as compared to typically deposited liner materials, such as silicon oxide.

FIG. 3D shows a cross sectional side view of substrate 821 with optional barrier layer 172A, covering liner 171. The barrier layer may include Ti or TiN and may be deposited using typical PVD or CVD techniques providing a barrier between a subsequently deposited copper via fill material and the polymer film liner 171.

FIG. 3E shows a shows a cross sectional side view of substrate 821 with via fill 172 covering barrier layer 172A and completely filling hole 193. The substrate 821 is now ready for subsequent processing as described with reference to FIGS. 4A-4H.

Vapor Phase Organic Polymer Film as a Gap Fill

FIGS. 4A-4H show a process 400 for forming TSVs and using a vapor phase polymer film as a gap fill material and via support material during wafer polishing. Once TSVs are filled with a conductive material such as copper, the back side of the wafer is thinned and polished using a CMP process to reveal the via material, i.e., copper. Due to the different polishing rates of silicon, copper and TSV liner materials, the polishing process creates stress on the copper and surrounding liner. Vapor phase polymer film deposition processes as described in FIG. 2 using a specific class of precursor can be used to deposit gap-fill polymers to support the copper via fill during subsequent polishing. A bottom-up polymer gap-fill process ensures a thorough filling of the gap between the filled TSVs and thus prevents exposed copper interconnects from damage during subsequent CMP polishing.

FIGS. 4A-4C are similar to FIGS. 3A-3E as discussed above and show the process of creating holes 193 in substrate 821 and filling holes 193 with liner 171, barrier layer 172A and via fill 172. Liner 171 may be the deposited organic polymer film as disclosed above, but alternatively, may be a different material such as silicon oxide.

FIG. 4D shows a side view of substrate 821 with a temporary carrier 192 bonded to the top surface of substrate 821. The top surface of silicon wafer 821 has been polished using a CMP polishing method so as to remove the top portion of the via fill 172, barrier 172A, and liner 171 revealing the top surface of substrate 821. The CMP polishing process is stopped once the silicon is exposed. A temporary carrier is bonded to the top surface of substrate 121 to provide additional support to substrate 821 and protection for the circuitry thereon, during subsequent chip package manufacturing processing.

The next step includes the thinning of the back side (bottom surface) of substrate 821 to reveal the TSV as shown in FIG. 4E. Gap 195 and contoured surface 196 are the result of the different polishing rates of silicon and copper. The overpolish of the softer silicon provides for gap 195 and contoured surface 196 as the CMP polishing step ends once the copper via fill 172 is exposed.

FIG. 4F shows substrate 821 with polymer film 180 deposited on the underside of substrate 821. Polymer film 180 fills the gaps caused by the CMP polish reveal step. Polymer film 180 is deposited using the vapor phase polymer deposition processes as described above in reference to FIG. 2. A bottom up-fill deposition of the polymer film is desired so as to fill the gaps and contours without conformally covering the surface of the substrate. Exemplary initiator source gases that may be used to achieve the desired bottom up-fill deposition results include tert-butyl peroxide (TBPO) and tert-amyl peroxide (TAPO). Exemplary monomer source gases that may be used to achieve the desired bottom up-fill results may include aromatic monomer source gases. In certain embodiments, the monomers may include, poly 4-vinyl pyridine, vinylimidazole, 1-3-diethynylbenzene, 4-vinyl pyridine, poly vinyl pyridine, 4-vinyl pyridine, polyphenylacetylene, divinylbenzene, poly divinylbenzene, glycidyl methacrylate, poly thiophene, dimethylaminomethylstyrene, trivinyltrimethoxy-cyclotrisiloxane, furfuryl methacrylate, cyclohexyl methacrylate-co-ethylene glycol dimethacrylate, pentafluorophenyl methacrylate-co-ethylene glycol diacrylate, 3,4-ethylenedioxythiophene and poly divinyl benzene cross linked with poly vinyl pyridine. Other monomer and initiator source gases as described herein, may also be used. The resulting polymer film fills the gaps without leaving any voids. Because polymer film 180 is deposited using a low temperature process, the film has low leakage rates and low dielectric constants. The bottom up-fill properties of the deposited film allows for the gaps in between the TSVs to be filled leaving minimal deposition on via fill 172 and surrounding layers. Silicon substrate 821 is now ready to for a subsequent polishing step to planarize the bottom surface of silicon substrate 821.

FIG. 4G shows substrate 821 after the subsequent CMP polishing step with via fill 172, barrier layer 172A and liner 171 structurally intact because of the support provided by the polymer film 180. Without polymer film 180 providing support between TSVs 178, the polishing step tends to crack and break the TSV interconnect fill materials.

FIG. 4H shows substrate 821 with the temporary carrier 192 removed and the TSV 178 filled with copper via fill 172 and ready for the next step in the wafer packaging process.

Vapor Phase Organic Polymer Film as an Underfill

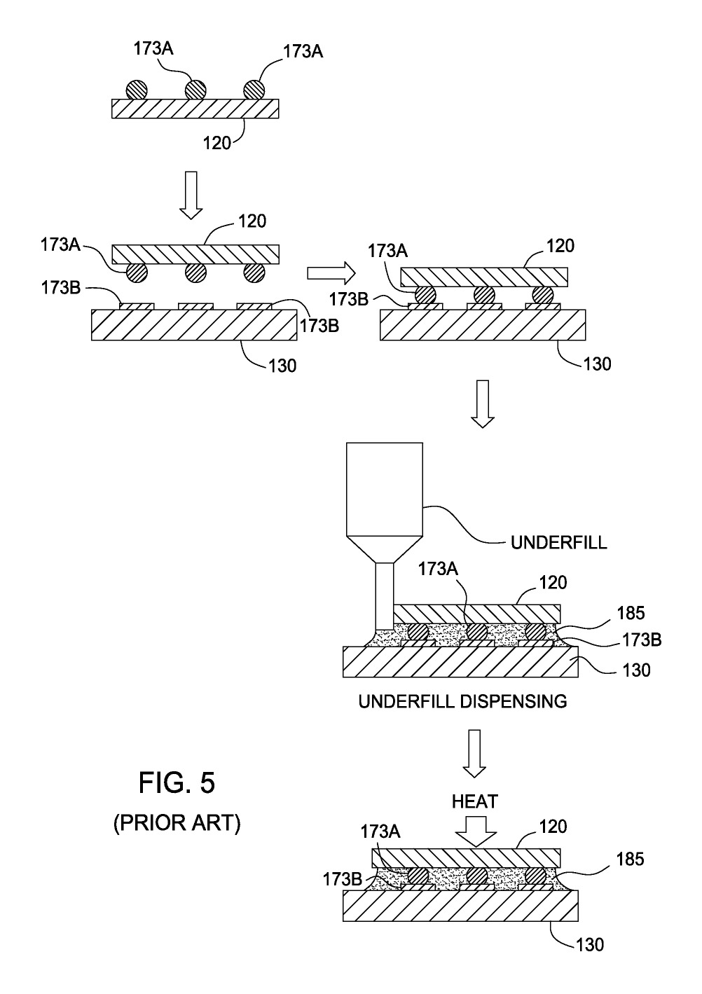

FIG. 5 illustrates a prior art method of depositing underfill material between a chip and substrate during a flip chip packaging process. The stacking of chips in 3D-IC packaging schemes requires solder balls 173A to be deposited on the surface of one chip 120 and to align with and provide a metallic connection on another chip 130 upon stacking. Solder balls 173A interconnect the circuitry of chip 120 to metal pad 173B formed on another chip 130 and/or to a laminate substrate. Once the chips are aligned, the solder is heated to reflow the solder balls and bond the circuitry of the two chips. The gap between the solder balls 173A/chips 120,130 is then filled with a material that protects the solder interconnects and provides the wafer stack with additional mechanical strength. As shown in FIG. 5, underfill 185 is applied after the wafer is stacked and the circuitry interconnected. The underfill materials, such as a polymer resin, is typically applied using a spin coating process. However, underfill materials that are applied by a spin coating process have several limitations including, the requirement for high temperature curing, high shrinkage and high moisture absorption. A flowable polymer necessary for the spin coating process contains solvents or volatile components that outgas during the curing process that leaves gaps in the material and can cause high Rc. Moisture absorption and outgassing leads to cracks in the wafer stack that inhibits performance and leads to the eventual delamination of the wafer stack.

FIG. 6 illustrates the use of a vapor phase organic polymer film as underfill material in a flip chip packaging process. The polymer film is deposited using the deposition techniques as described in reference to FIG. 2. A polymer film deposited using a vapor phase deposition process ensures a dense packing of void-free underfill polymer material between interconnects, provides a low moisture content and no outgassing as there is no need for high temperature curing.

As shown in FIG. 6, chip 120 includes solder balls 173a deposited on and connected to circuitry therein. Polymer film 175 is deposited on the surface of chip 120 and solder balls 173A using a vapor phase organic polymer deposition process described herein with reference to FIGS. 1 and 2. The desired polymer film may be a gap-free conformal film or bottom-up fill film and have a desired CTE to closely match the substrate materials of the surrounding chips. Exemplary monomer source gases that may be used to provide the underfill requirement may include glicidyl methacrylate (GMA), divinyl benzene, 4-vinyl pyridine, poly glicidyl methacrylate cross-linked with divinyl benzene, divinyl benzene cross-linked with poly vinyl pyridine. Exemplary intitiator that may be used to provide the underfill material requirements may include tert-butyl peroxide (TBPO) and tert-amyl peroxide (TAPO). Other monomer and initiator source gases as described herein, may also be used.

Once the organic polymer film 175 is deposited, chip 120 is then flipped over and placed on chip 130 and aligned so that solder balls 173A are in contact with metal pads 173B assuring conductive contact between the chips. The chip stack is then heated at a temperature between 50° C. and 70° C. to reflow the solder and bind the substrates. This low temperature process step eliminates the wafer bowing issues associated with high temperature curing steps required with the spin coat polymer underfill process. In certain embodiments, polymer film 175 may also be applied to the top surface of chip 130 so that upon heat treatment the two polymer layers between chips 120 and 130 bind together further enhancing the structural strength of the wafer package. In certain embodiments, upon the deposition of a conformal vapor phase polymer film, an additional step of exposing the polymer film to an etching process or CMP process to expose the metal pad or solder ball prior to stacking the chips ensures a clean metal interconnect contact between the chips.

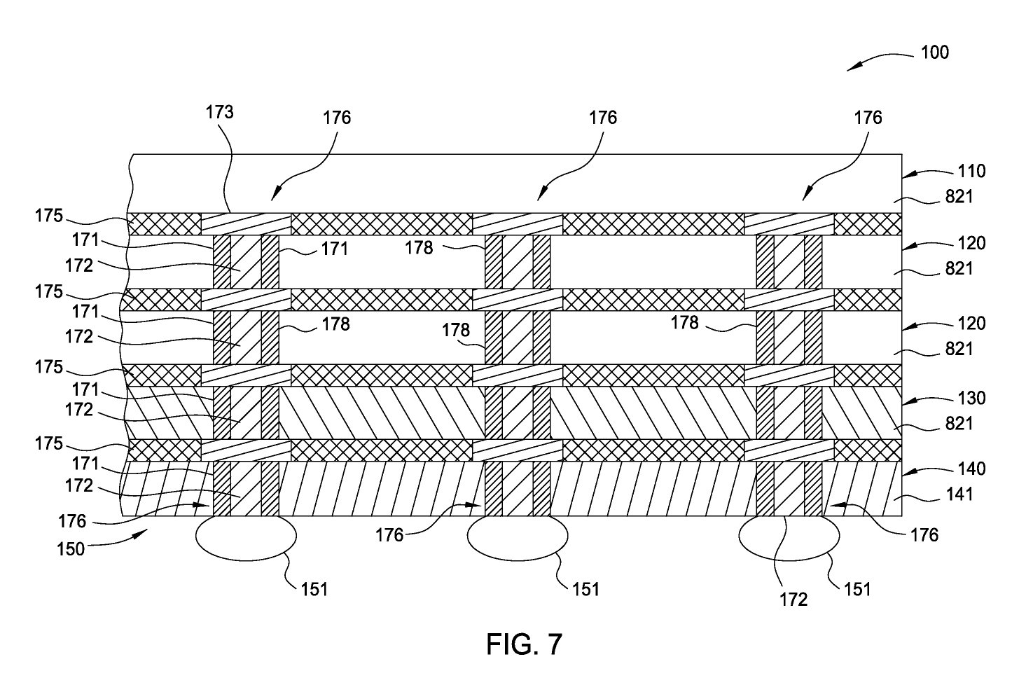

FIG. 7 illustrates a cross-sectional view of a portion of a multi-chip stack structure of a semiconductor package and identifies the different locations within the chip package where a vapor phase organic polymer film may be used to enhance the package. Chip package 100 includes multiple chips arranged in a typical 3D-IC package scheme with memory chips 110 and 120 stacked on logic chip 130 and laminate substrate 140. Through silicon vias (TSVs) 178 provide a pathway through silicon substrates 821 and through laminate substrate 140 to the solder balls 151 positioned on the underside 150 of laminate substrate 140. For example, TSV 178 provides a pathway between memory chip 110 and the solder balls 151 attached to the underside 150 of laminate substrate 140. TSV 178 passes through the material 141 of laminate substrate 140, the silicon substrate 821 of logic chip 130, and silicon substrate 821 of memory chips 120. As shown, TSV 178 does not extend through silicon substrate 821 of memory chip 110, but in certain embodiments where an additional chip may be packaged above memory chip 110, the package design scheme may include a TSV through silicon substrate 821 of memory chip 110 to connect to any additional chips stacked and attached above memory chip 110. Wafer interconnect 176 provides the conductive interconnect between wafers, and as shown includes solder cap 173, via fill 172 and via liners 171. Solder cap 173 provides a bond and conductive connection between the metal contacts of each wafer or substrate. Typical metal contacts include metal bumps or pads that connect the circuitry of one silicon layer to the circuitry of another. Via fill 172 provides the conductive material that fills the TSV that interconnect the wafers. Via fill 172 is typically copper or other highly conductive metal. Liner 171 provides an insulative layer between the conductive material used as via fill 172 and the surrounding silicon and circuitry. Polymer film 175 is the underfill material that fills the gap between chips 110, 120 and 130 and/or the chips and substrate 140 and between the solder caps 173 to provide adhesion and support for the stacked chip structure.

Thus, as disclosed herein, a vapor phase organic polymer film deposited using a process PHCVD process produces a versatile film with many benefits that can be tailored to specific criteria and utilized in a flip-chip wafer level packing scheme. The vapor phase organic film may be used as TSV liner 171 insulating the silicon substrate from via fill 172, and as underfill polymer film 175 with gap-free, low moisture content and good adhesion properties that minimize wafer delamination. Furthermore, a vapor phase organic film provides a good gap fill and TSV support material useful during the TSV reveal wafer thinning process.

While the foregoing is directed to embodiments of the present invention, other and further embodiments of the invention may be devised without departing from the basic scope thereof, and the scope thereof is determined by the claims that follow.

1. A method of processing a substrate, comprising:
depositing a polymer layer over a surface of a substrate having solder disposed thereon using a low temperature CVD technique; and
bonding the substrate to an external circuitry by heating the solder.

2. The method of claim 1, wherein the solder is configured in solder bumps on the surface of the substrate and the polymer layer is deposited on the substrate and on the solder bumps.

3. The method of claim 1, further comprising:
placing the surface of the substrate having a solder material and the deposited organic polymer layer on a surface of the external circuitry.

4. The method of claim 1, further comprising:
curing the solder material and the polymer layer at a temperature between about 50° C. and about 70° C. to bond the external circuitry and the substrate.

5. The method of claim 1, wherein the CVD technique comprises:
flowing a monomer into a processing region of a process chamber and forming the polymer layer from the monomer.

6. The method of claim 5, wherein the monomer is selected from the group consisting of ethyleneglycol diacrylate, t-butylacrylate, N,N-dimethylacrylamide, vinylimidazole, 1-3-diethynylbenzene, 4-vinyl pyridine, poly vinyl pyridine, poly 4-vinyl pyridine, polyphenylacetylene, N,N-dimethylaminoethylmethacrylate, divinylbenzene, poly divinylbenzene, glycidyl methacrylate, poly thiophene, ethyleneglycol dimethacrylate, tetrafluoroethylene, dimethylaminomethylstyrene, perfluoroalkyl ethyl methacrylate, trivinyltrimethoxy-cyclotrisiloxane, furfuryl methacrylate, cyclohexyl methacrylate-co-ethylene glycol dimethacrylate, pentafluorophenyl methacrylate-co-ethylene glycol diacrylate, 2-hydroxyethyl methacrylate, methacrylic acid, 3,4-ethylenedioxythiophene, and combinations thereof.

7. The method of claim 5, wherein the monomer is flown into the process chamber at a temperature of between about 55° C. and about 75° C.

8. The method of claim 5, wherein the CVD technique further comprises:
flowing an initiator into the processing region through one or more filament wires heated to a temperature between about 200° C. and about 450° C.

9. The method of claim 5, wherein the initiator is selected from the group consisting of perfluorooctane sulfonyl fluoride (PFOS), perfluorobutane-1-sulfonyl fluoride (PFBS), triethylamine (TEA), tert-butyl peroxide (TBPO), 2,2′-azobis (2-methylpropane), tert-amyl peroxide (TAPO), di-tert-amyl peroxide, antimony pentachloride, benzophenone, and combinations thereof.

10. The method of claim 1, wherein the polymer layer comprises a polymer selected from the group consisting of poly(glycidyl methacrylate-co-divinylbenzene), poly(glycidyl methacrylate-co-methacrylamide), poly(ethyleneglycol diacrylate), poly(t-butylacrylate), poly N,N-dimethylacrylamide, poly(vinylimidazole), poly(1-3-diethynylbenzene), poly(phenylacetylene), poly(N,N-dimethylaminoethylmethacrylate) (p(DMAM), poly (divinylbenzene), poly(glycidyl methacrylate) (p(GMA)), poly (ethyleneglycol dimethacrylate), poly (tetrafluoroethylene), poly(tetrafluoroethylene) (PTFE), poly(dimethylaminomethylstyrene) (p(DMAMS), poly(perfluoroalkyl ethyl methacrylate), poly(trivinyltrimethoxy-cyclotrisiloxane), poly(furfuryl methacrylate), poly(cyclohexyl methacrylate-co-ethylene glycol dimethacrylate), poly(pentafluorophenyl methacrylate-co-ethylene glycol diacrylate), poly(2-hydroxyethyl methacrylate-co-ethylene glycol diacrylate), poly(methacrylic acid-co-ethylene glycol dimethacrylate), poly(3,4-ethylenedioxythiophene), and combinations thereof.

11. The method of claim 1, wherein the polymer layer is deposited over the surface of the substrate at a substrate temperature of between 20° C. and about 75° C.

12. The method of claim 1, wherein the polymer layer is deposited conformally over the surface of the substrate to a thickness between 50 angstroms and 1000 angstroms at a deposition rate of between 10 angstrom per minute and 500 angstroms per minute.

13. The method of claim 12, further comprising forming a barrier layer conformally over the polymer layer formed on the surface of the substrate and the sidewalls of the one or more holes.

14. The method of claim 1, wherein the external circuitry comprises a memory device.

15. The method of claim 1, wherein the external circuitry comprises a laminate substrate.

16. The method of claim 1, wherein the external circuitry comprises a logic device.

17. A method of processing a substrate, comprising:
forming one or more holes into or through a substrate;
forming a polymer liner conformally over a surface of the substrate and on sidewalls of the one or more holes using a low temperature CVD technique; and
filling the one or more holes with a conductive material.

18. The method of claim 17, wherein the CVD technique comprises:
flowing a monomer into a processing region of a process chamber and forming the organic polymer layer from the monomer.

19. The method of claim 18, wherein the conductive material comprises copper.

20. A method of processing a substrate, comprising polishing the surface of a substrate, the substrate having holes therein that are filled with conductive material and stopping the polishing upon reaching the conductive material;
forming a polymer film over the substrate using a low temperature CVD technique; and
polishing the polymer film and stopping the polishing upon reaching the conductive material.
